(19) United States
(12) Patent Application Publication
(10) Pub. No.: US 2024/0003012 A1
(43) Pub. Date: Jan. 4, 2024

(54) SUBSTRATE PROCESSING APPARATUS, HEATING APPARATUS, METHOD OF PROCESSING SUBSTRATE AND METHOD OF MANUFACTURING SEMICONDUCTOR DEVICE

(71) Applicant: Kokusai Electric Corporation, Tokyo (JP)

(72) Inventor: Yuji TAKEBAYASHI, Toyama-shi (JP)

(73) Assignee: Kokusai Electric Corporation, Tokyo (JP)

(21) Appl. No.: 18/469,121

(22) Filed: Sep. 18, 2023

Related U.S. Application Data
(63) Continuation of application No. PCT/JP2021/013598, filed on Mar. 30, 2021.

(51) Int. Cl. C23C 16/46; H05B 3/44

(52) U.S. Cl. CPC C23C 16/46; H05B 3/44

(57) ABSTRACT

A technique including: a process chamber in which a substrate is processed; a heater configured to heat the substrate in the process chamber; and a housing including the heater and the process chamber, in which the heater includes: an outer tube; an inner tube disposed inside the outer tube; and a heater wire including a power line disposed in an inner space of the inner tube and a power line that is different from the power line disposed in the inner space of the inner tube and is disposed between the outer tube and the inner tube.

### CROSS-REFERENCE TO RELATED APPLICATION

This application is a bypass continuation application of PCT International Application No. PCT/JP2021/013598, filed on Mar. 30, 2021, in the WIPO, the entire contents of which are hereby incorporated by reference.

### BACKGROUND

### Field

The present disclosure relates to a substrate processing apparatus, a heating apparatus, a substrate processing method, and a method of manufacturing a semiconductor device.

### Description of the Related Art

In general, in a process of manufacturing a semiconductor device, used is a substrate processing apparatus that performs predetermined process processing to a substrate, such as a wafer. Such process processing is, for example, film-forming processing in which a plurality of types of gas is supplied in sequence. In order to perform such film-forming processing, in some cases, a predetermined heater heats a substrate.

### SUMMARY

According to the present disclosure, there is provided a technique enabling a high efficiency of heating.

According to an embodiment of the present disclosure, there is a technique that includes:
a process chamber in which a substrate is processed;
a heater configured to heat the substrate in the process chamber; and
a housing including the heater and the process chamber, in which
the heater includes:
an outer tube;
an inner tube disposed inside the outer tube; and
a heater wire including a power line disposed in an inner space of the inner tube and a power line that is different from the power line disposed in the inner space of the inner tube and is disposed between the outer tube and the inner tube.

### BRIEF DESCRIPTION OF THE DRAWINGS

FIG. 1A is a schematic configuration view of a substrate processing apparatus favorably used in an embodiment of the present disclosure and is also a plan view of a process container from top. FIG. 1B is a sectional view of the process container taken along line B-B of FIG. 1A. FIG. 1C is a sectional view of the process container taken along line C-C of FIG. 1A.

FIG. 2A is a schematic longitudinal sectional view of a heater favorably used in the embodiment of the present disclosure. FIG. 2B is a sectional view of the heater favorably used in the embodiment of the present disclosure taken along line D-D of FIG. 2A.

FIG. 3 is a schematic configuration view of a substrate processing apparatus favorably used in another embodiment of the present disclosure and is also a plan view of a process container.

FIG. 4A is a plan view of a process container favorably used in another embodiment of the present disclosure and is also an explanatory view for the number of disposed heaters. FIG. 4B is a plan view of a process container favorably used in another embodiment of the present disclosure and is also an explanatory view for the number of disposed heaters and the number of wafers to be processed. FIG. 4C is a plan view of a process container favorably used in another embodiment of the present disclosure and is also an explanatory view for the number of disposed heater and the number of wafers to be processed.

### DETAILED DESCRIPTION

### Embodiment of the Present Disclosure

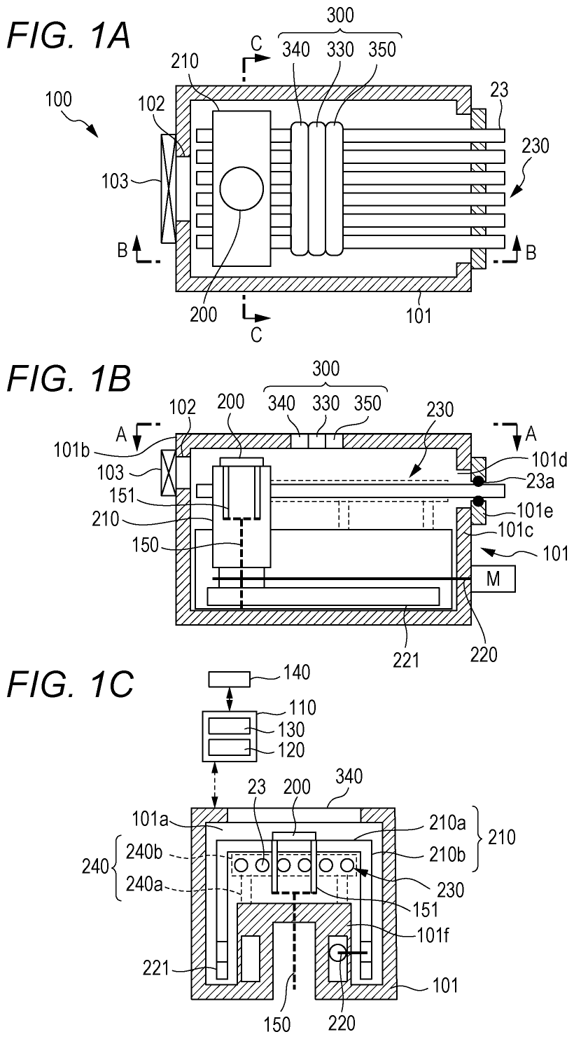

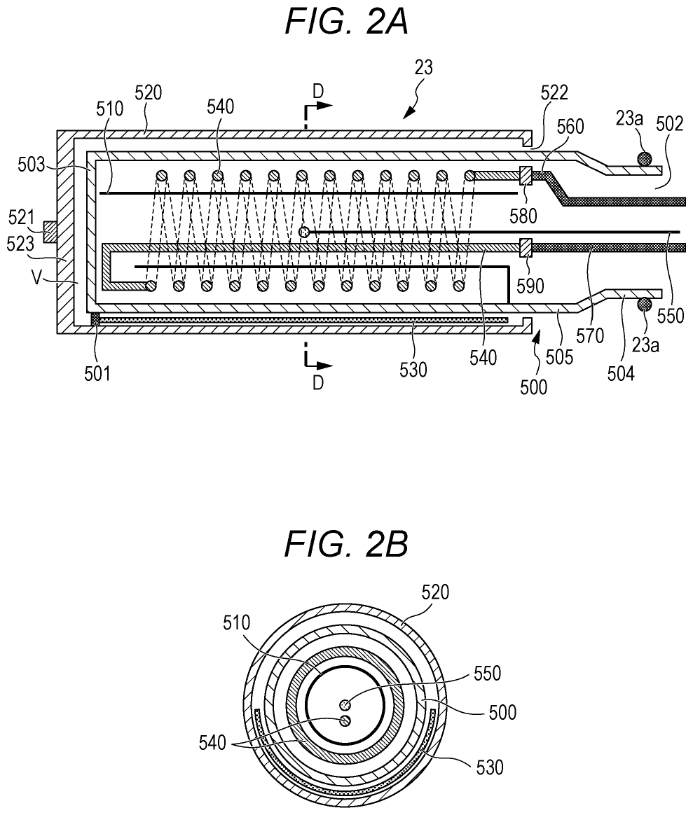

An embodiment of the present disclosure will be described below mainly with reference to FIGS. 1A to 2B. Note that the drawings used in the following description are all schematic and thus, for example, the dimensional relationship between each constituent element and the ratio between each constituent element in the drawings do not necessarily coincide with realities. In addition, for example, a plurality of drawings does not necessarily coincide with each other in the dimensional relationship between each constituent element or in the ratio between each constituent element.

(1) Entire Configuration of Substrate Processing Apparatus

A substrate processing apparatus 100 includes a process container 101 serving as a housing for processing to a wafer 200. The process container 101 serves as a sealed container formed of a metal material, such as aluminum (Al) or stainless steel (SUS). Inside the process container 101, namely, in a hollow, formed is a process chamber 101a serving as a process space for processing to a wafer 200. The process container 101 has a side wall 101b provided with a wafer access port 102 and a gate valve 103 that opens/shuts the wafer access port 102 such that a wafer 200 can be transferred into/from the process container 101 through the wafer access port 102. The process container 101 has a side wall 101c, opposite the side wall 101b, provided with an opening 101d having an upper portion and a lower portion near which walls 101e are provided one-to-one as part of the side wall 101c. As illustrated in FIG. 1C, in sectional view along the longitudinal direction of the process container 101, the process container 101 has a bottom provided with a protrusion structure 101f serving as part of the bottom. Furthermore, the process container 101 has a gas exhauster including a vacuum pump and a pressure controller (not illustrated) connected thereto such that the pressure in the process container 101 can be regulated to a predetermined pressure by the gas exhauster.

Inside the process container 101, provided is a substrate mounting stage 210 serving as a substrate mounting table on which a wafer 200 is mounted and supported. The substrate mounting stage 210 is gate-shaped in sectional view as illustrated in FIGS. 1C and 1s rectangular in shape in plan view as illustrated in FIG. 1A. More specifically, the substrate mounting stage 210 includes a substrate mounting face 210a on which a wafer 200 is mounted and two side plates 210b extending downward one-to-one from both sides of the substrate mounting face 210a. The side plates 210b each have a lower end secured slidably to a guide rail 221.

For direct contact with a wafer 200, desirably, the substrate mounting face 210a is formed of a material, such as quartz (SiO₂) or alumina (Al₂O₃). For example, preferably, a susceptor, serving as a support plate formed of quartz or alumina, is mounted on the substrate mounting face 210a and then a wafer 200 is mounted and supported on the susceptor.

As illustrated in FIGS. 1B and 1C, the substrate mounting stage 210 (side plate 210b) has a lower end coupled with a slider 220 serving as a mover that reciprocates the substrate mounting stage 210 and the wafer 200 on the substrate mounting face in the process container 101. The slider 220 is secured to nearby the bottom of the process container 101. The slider 220 is capable of reciprocating the substrate mounting stage 210 and the wafer 200 on the substrate mounting face, horizontally, between one end and the other end in the longitudinal direction of the process container 101. For example, the slider 220 can be achieved with a feed screw (ball screw) and a drive source, such as an electric motor M, in combination.

Below the substrate mounting face 210a of the substrate mounting stage 210, disposed is a heater unit 230 that heats a wafer 200. The heater unit 230 includes a plurality of heaters 23 (e.g., six heaters 23). Such a heater 23 is also referred to as a heating apparatus. The heaters 23 are each substantially cylindrical in shape and are each disposed along the longitudinal direction of the process container 101.

Note that the heater unit 230 is secured inside the substrate mounting stage 210, and the substrate mounting stage 210 slides outside the heater unit 230.

The heater unit 230 (heaters 23) is supported by a support 240. The support 240 includes a prop 240a and a box 240b. The heater unit 230 is supported by the box 240b that is open upward and is disposed at the upper end of the prop 240a provided on the bottom (protrusion structure 101f) of the process container 101.

The heater unit 230 is provided ranging from one end to the other end in the longitudinal direction of the process container 101. One end in the longitudinal direction of the heater unit 230 is disposed near the side wall 101b in the process container 101 and the other end having penetrated through the opening 101d with which the side wall 101c is provided is supported from above and below by the walls 101e. The longitudinal direction of the heater unit 230 (heaters 23) is identical to the direction of movement of the substrate mounting stage 210. The configuration of the heater unit 230 (heaters 23) will be described in detail later.

A wafer lifter 150 is on standby below the substrate mounting stage 210 (substrate mounting face 210a). A plurality of lifting pins 151 (e.g., three lifting pins 151) is disposed on the wafer lifter 150. The wafer lifter 150 lifts up/down the lifting pins 151. The wafer lifter 150 and the lifting pins 151 are, as described later, for use in loading/unloading a wafer 200. The substrate mounting stage 210 is provided with through holes (not illustrated), through which the lifting pins 151 penetrate one-to-one, at positions corresponding to the lifting pins 151.

Above the substrate mounting stage 210, provided is a cartridge head assembly 300 serving as a gas supplier to the wafer 200 on the substrate mounting stage 210. The cartridge head assembly 300 is larger in size than the entire wafer 200 and is provided ranging from one end to the other end in the lateral direction of the process container 101.

As illustrated in FIG. 1A, for example, the cartridge head assembly 300 includes a single source-gas cartridge 330 and reactant-gas cartridges 340 and 350. The reactant-gas cartridges 340 and 350 are disposed such that the source-gas cartridge 330 is interposed therebetween.

The source-gas cartridge 330 includes a source-gas supply line (not illustrated), a source-gas exhaust line (not illustrated), an inert-gas supply line (not illustrated), and an inert-gas exhaust line (not illustrated), in which a common exhaust line may be provided as the source-gas exhaust line and the inert-gas exhaust line. The reactant-gas cartridges 340 and 350 each include a reactant-gas supply line (not illustrated), a reactant-gas exhaust line (not illustrated), an inert-gas supply line (not illustrated), and an inert-gas exhaust line (not illustrated), in which a common exhaust line may be provided as the reactant-gas exhaust line and the inert-gas exhaust line. For space separation of source gas and reactant gas, each supply line has an on/off valve (not illustrated), a mass flow controller (not illustrated) that controls a flow rate, and a gas supply source (not illustrated) disposed therein and each exhaust line has a pressure controller (not illustrated) and an exhaust pump (not illustrated) disposed therein.

As the source gas, for example, used can be a silane-based gas containing silicon (Si) serving as a main element for a film to be formed on a wafer 200. As the silane-based gas, for example, used can be gas containing Si and halogen, namely, halosilane gas. Halogen includes, for example, chlorine (CI), fluorine (F), bromine (Br), and iodine (I). As the halosilane gas, for example, used can be chlorosilane gas containing Si and Cl. Specifically, dichlorosilane (SiH₂Cl₂, abbreviation: DCS) gas or hexachlorodisilane (Si₂Cl₆, abbreviation: HCDS) gas can be used. As the source gas, gas containing a metal, such as titanium (Ti), can be used, in addition to the chlorosilane gas. As a Ti-containing gas, for example, used can be titanium tetrachloride (TiCl₄) gas.

As the reactant gas, for example, used can be a nitrogen (N)/hydrogen (H)-containing gas serving as nitriding gas (nitriding agent). Examples of the reactant gas that can be used include hydronitrogen-based gases, such as ammonia (NH₃) gas, diazene (N₂H₂) gas, hydrazine (N₂H₄) gas, and N₃H₈ gas.

Examples of inert gas that can be used include nitrogen (N₂) gas and rare gases, such as argon (Ar) gas, helium (He) gas, neon (Ne) gas, and xenon (Xe) gas.

As illustrated in FIG. 1C, the substrate processing apparatus 100 includes a controller 110 that controls the operation of each constitute of the substrate processing apparatus 100. The controller 110 serves as a computer including at least an arithmetic section 120 and a memory 130 serving as hardware resources. The controller 110 is connected to each constituent described above. In response to an instruction from a higher-level controller or an operator, the controller 110 reads, from the memory 130, a control program or a process recipe (hereinafter, these are collectively and simply referred to as a “program”) serving as predetermined software and then controls the operation of each constituent in accordance with the description thereof. That is, the controller 110 executes, with the hardware resources, the program serving as the predetermined software, so that the operation of each constituent of the substrate processing apparatus 100 is controlled due to the hardware resources and the predetermined software in cooperation. Note that, in the present specification, in some cases, the term “program” indicates the control program, the process recipe, or both thereof.

The controller 110 as above may be a dedicated computer or may be a general-purpose computer. For example, an external memory 140 storing the program described above is prepared and then the program is installed on a general-purpose computer through the external memory 140, so that the controller 110 in the present embodiment can be achieved. Note that examples of the external memory 140 include a magnetic tape, a magnetic disk, such as a flexible disk or hard disk, an optical disc, such as a CD or DVD, a magneto-optical disc, such as an MO, and a semiconductor memory, such as a USB memory or a memory card. For supply of the program to a computer, the supply through the external memory 140 is not limiting. For example, the program may be supplied through the Internet or a dedicated line or from a higher-level apparatus through a receiver, instead of through the external memory 140.

The memory 130 in the controller 110 and the external memory 140 connectable to the controller 110 each serve as a computer-readable recording medium. Hereinafter, such memories are collectively and simply referred to as a “recording medium”. Note that, in the present specification, in some cases, the term “recording medium” indicates the memory 130, the external memory 140, or both thereof.

(2) Configuration of Heater 23

As illustrated in FIGS. 2A and 2B, a heater 23 includes, mainly, a main heater tube 500 serving as an outer tube, an insulating tube 510 serving as an inner tube, and a heat emitter 540 serving as a heater wire.

The main heater tube 500 includes a main body 505 substantially cylindrical in shape. The main body 505 has an end, in its longitudinal direction (axial direction), provided with a support target 504 to be supported by the walls 101e outside the opening 101d of the process container 101 for setting to the process container 101. The main body 505 (support target 504) has the end provided with an opening 502 enabling the heat emitter 540 in communication and the other end provided with a lid 503. The opening 502 (support target 504) is provided with an O-ring 23a enabling the main heater tube 500 to retain internal airtightness after the main heater tube 500 (heater 23) is set to the process container 101.

Outside the main heater tube 500, provided is a reflector protective tube 520 covering the outer circumference of the main heater tube 500. The main heater tube 500 is inserted inside the reflector protective tube 520 substantially cylindrical in shape.

Between the reflector protective tube 520 and the main heater tube 500, provided is an aligner 501 that aligns the position of the main heater tube 500 inside the reflector protective tube 520. More specifically, the reflector protective tube 520 substantially cylindrical in shape has an inner circumferential face provided with the aligner 501 for alignment such that friction occurs to the main heater tube 500 to prevent the reflector protective tube 520 from sliding. The provision of the aligner 501 as above enables alignment of the position of the main heater tube 500 inside the reflector protective tube 520. Thus, for example, during transfer of the heater 23, misalignment can be avoided between the reflector protective tube 520 and the main heater tube 500. Note that, for example, the main heater tube 500 may be provided with the aligner 501, provided that the aligner 501 can set the positional relationship between the main heater tube 500 and the reflector protective tube 520.

For example, the main heater tube 500 is formed of quartz.

The reflector protective tube 520 includes a cylinder having an end, in its longitudinal direction (axial direction), provided with an opening 522 and the other end provided with a lid 523. The reflector protective tube 520 has a cavity based on the cylinder and the lid 523, and the space of the cavity is filled with a vacuum atmosphere or an inert-gas atmosphere. For a vacuum atmosphere in the space, for example, the air in the space is sucked through a suction/supply port 521 with which the lid 523 of the reflector protective tube 520 is provided. For an inert-gas atmosphere in the space, inert gas is supplied into the space through the suction/supply port 521. In both cases, the space is kept depressurized. Note that, for example, the suction/supply port 521 also functions as a seal that prevents the inert gas from leaking outward from the space.

For example, a reflector 530 semicylindrical in shape is disposed in the space of the cylinder of the reflector protective tube 520 such that the reflector 530 is open toward the process chamber 101a above. A gap V is provided between the lid 503 of the main heater tube 500 and the lid 523 of the reflector protective tube 520.

The reflector 530 is higher in thermal reflectivity than the bottom wall of the process container 101 disposed below the heater 23.

For example, the reflector protective tube 520 is formed of quartz. For example, the reflector 530 is formed of molybdenum (MO) or platinum (Pt).

The insulating tube 510 cylindrical in shape is disposed inside the main heater tube 500. For example, the insulating tube 510 is formed of a ceramic material, such as alumina (Al₂O₃), magnesia (MgO), zirconia (ZrO₂), or aluminum titanate (Al₂O₃·TiO₂), quartz, or SiC.

The heat emitter 540 serving as a heater wire is disposed inside the main heater tube 500. The heat emitter 540 is wound spirally at predetermined pitches such that the insulating tube 510 is disposed inside the spiral. Between the main heater tube 500 and the insulating tube 510, disposed is a power line (e.g., a power supply line) 560 connected to the heat emitter 540 through a sleeve 580. In the inner space of the insulating tube 510, disposed is a power line (e.g., a power output line) 570 connected to the heat emitter 540 through a sleeve 590. The power lines 560 and 570 are disposed inside the support target 504 of the main heater tube 500. For example, the current supplied from the power line 560 flows through the heat emitter 540 to cause the heat emitter 540 to generate heat.

Below the heater 23, provided is the slider 220 that moves the wafer 200 (substrate mounting stage 210). The reflector 530 is provided between the heat emitter 540 and the slider 220. In addition, the reflector 530 is provided between the heat emitter 540 and the wafer lifter 150. Such an arrangement enables prevention of heat transfer to the slider 220 and the wafer lifter 150 that require no heating below the reflector 530. Such prevention of heat transfer as above is desirable because the slider 220 and the wafer lifter 150 each include, for example, a component and grease sensitive to heat.

Inside the insulating tube 510, disposed is a thermocouple 550 that controls/monitors the temperature of the heat emitter 540. The degree of energization of the heater 23 is feedback-controlled based on temperature information detected by the thermocouple 550. Thus, the heater 23 enables retention of the temperature of the wafer 200 supported by the substrate mounting stage 210 at a predetermined temperature.

(3) Substrate Processing Process

Next, a process of forming a thin film onto a wafer 200 with the substrate processing apparatus 100 will be described as a partial process in a process of manufacturing a semiconductor device. Note that, in the following description, the controller 110 controls the operation of each constituent of the substrate processing apparatus 100.

In the present embodiment, exemplified will be a case where HCDS gas is supplied as source gas through the source-gas supply line, N₂ gas is supplied as inert gas through each inert-gas supply line, and NH₃ gas is supplied as reactant gas through each reactant-gas supply line.

(Substrate Loading Step: S101)

In a substrate loading step S101, a wafer 200 is loaded into the process container 101. Specifically, with the gate valve 103, which is provided at the wafer access port 102 with which the side wall 101b of the process container 101 of the substrate processing apparatus 100 is provided, open, a wafer transferer (not illustrated) loads a wafer 200 into the process container 101. In this case, the wafer lifter 150 rises to the position at which the wafer 200 is loaded (transferred), so that the wafer 200 is mounted on the upper ends of the lifting pins 151. After that, the wafer lifter 150 falls, so that the wafer 200 is mounted on the substrate mounting face 210a of the substrate mounting stage 210. Then, the wafer transferer moves outward from the process container 101, and the process container 101 is hermetically sealed internally due to occlusion of the wafer access port 102 based on shutting of the gate valve 103.

(Pressure/Temperature Regulation Step: S102)

After the wafer 200 loaded into the process container 101 is mounted on the substrate mounting face 210a, in a pressure/temperature regulation step S102, the pressure and temperature in the process container 101 are regulated. In this case, for example, the heaters 23 are each supplied with power based on the value detected by the thermocouple 550 such that the wafer 200 has a desired processing temperature, such as a predetermined temperature in the range of 400 to 750° C. The wafer 200 is heated continuously at least until processing to the wafer 200 finishes.

(Substrate Processing Step: S103)

After the pressure in the process container 101 reaches a desired processing pressure and the temperature of the wafer 200 reaches a desired processing temperature, a substrate processing step S103 is performed. In the substrate processing step S103, the source-gas cartridge 330 and the reactant-gas cartridges 340 and 350 each supply processing gas. Specifically, the source-gas cartridge 330 supplies HCDS gas and N₂ gas, downward. The N₂ gas functions as a gas shield such that the HCDS gas is prevented from spreading below the reactant-gas cartridges 340 and 350, that is, the HCDS gas is separated spatially from the other spaces. The reactant-gas cartridges 340 and 350 each supply NH₃ gas, downward. With a matcher (not illustrated) and a radio-frequency power supply (not illustrated), plasma is generated in the space on the lower side of each of the reactant-gas cartridges 340 and 350.

In parallel with the supply of the gases, the gas exhauster operates to control the process chamber 101a to be kept at a desired pressure. In response to stable space separation under the source-gas cartridge 330, the slider 220 is driven to reciprocate the substrate mounting stage 210, on which the wafer 200 is mounted, between the reactant-gas cartridge 340, the source-gas cartridge 330, and the reactant-gas cartridge 350. Thus, the wafer 200 passes under the source-gas cartridge 330 and the reactant-gas cartridges 340 and 350.

A clarified flow of the wafer 200 with the source gas and the reactant gas focused on is given in the following description. The surface of the wafer 200 is exposed to various types of gas in the following order. Such exposure is defined as one cycle and is repeated to form a desired film.

HCDS gas (source-gas cartridge 330)->NH₃ gas (reactant-gas cartridge 350)->HCDS gas (source-gas cartridge 330)->NH₃ gas (reactant-gas cartridge 340)

Under the source-gas cartridge 330, the HCDS supplied on the wafer 200 is decomposed to form a Si-containing layer. Next, under the reactant-gas cartridge 350, NH₃ in a plasma state is supplied to the Si-containing layer formed under the source-gas cartridge 330 to modify the Si-containing layer, resulting in formation of a SiN layer. Next, under the source-gas cartridge 330, a Si-containing layer is formed on the SiN layer resulting from the modification under the reactant-gas cartridge 350. Next, under the reactant-gas cartridge 340, NH₃ plasma is supplied to the Si-containing layer formed under the source-gas cartridge 330 to modify the Si-containing layer, resulting in formation of a SiN layer. Thus, the processing described above is performed to the wafer 200 with the substrate mounting stage 210 reciprocating, so that a desired film can be formed.

Exemplary processing conditions in the substrate processing step S103 are as follows:
Processing temperature: 400 to 750° C., preferably, 600 to 700° C.
Processing pressure: 10 to 3000 Pa, preferably, 50 to 300 Pa
The flow rate of supply of HCDS gas: 0.1 to 1.0 slm, preferably, 0.25 to 0.5 slm
The flow rate of supply of NH₃ gas (in each line): 0.1 to 3.0 slm, preferably, 0.5 to 1.0 slm
The flow rate of supply of N₂ gas (in each line): 0.1 to 3.0 slm, preferably, 0.5 to 1.0 slm
Time per cycle: 0.5 to 30 seconds

After a SiN film having a predetermined composition and a predetermined thickness is formed on the wafer 200, N₂ gas is supplied as purge gas from the inert-gas supply lines into the process container 101 and then is exhausted through the exhaust lines. Thus, a purge is made in the process container 101, so that the residual gas and any reaction by-product in the process container 101 are removed from the process container 101. After that, the atmosphere in the process container 101 is replaced with the inert gas (Inert gas replacement) and the pressure in the process container 101 is changed to a predetermined transfer pressure or is restored to the normal pressure (atmospheric pressure restoration).

(Substrate Unloading Step: S104)

In response to formation of a desired film in the substrate processing step S103, a substrate unloading step S104 is performed. The substrate unloading step S104 is reverse in procedure to the substrate loading step S101, in which the wafer transferer unloads the processed wafer 200 outward from the process container 101.

A series of processing from the substrate loading step S101 to the substrate unloading step S104 described above is performed per wafer 200 serving as a processing target. That is, every time the wafer 200 is replaced with another wafer 200, the series of processing S101 to S104 described above is performed a predetermined number of times. In response to completion of processing to all wafers 200 serving as processing targets, the substrate processing process finishes.

(4) Effects According to the Present Embodiment

According to the present embodiment, the following effects can be obtained.

(a) Each heater 23 includes the insulating tube 510 inside, in which the heat emitter 540 is provided with the power line 570 disposed in the inner space of the insulating tube 510 and with the power line 560, different from the power line 570, disposed between the main heater tube 500 and the insulating tube 510 and is wound spirally such that the insulating tube 510 is disposed inside the spiral. Thus, the heat emitter 540 can be prevented from being short-circuited. Thus, the heat emitter 540 being smaller in diameter in sectional view along the longitudinal direction of the heater 23 contributes to the heater 23 being smaller in size. As a result, a substrate processing apparatus smaller in size can be achieved. The heat emitter 540 connected to the power line 570 disposed in the inner space of the insulating tube 510 is disposed inside the insulating tube 510, contributing to the heater 23 being smaller in size. As a result, a substrate processing apparatus smaller in size can be achieved.

(b) Since the insulating tube 510 is formed of an insulator, the heat emitter 540 can be wound around the insulating tube 510, leading to a further reduction in the size of the heater 23. As a result, a substrate processing apparatus smaller in size can be achieved.

(c) Since the reflector 530 is protected in the reflector protective tube 520, the reflector 530 can be inhibited from being exposed to the open air, so that an improvement can be made in the efficiency of heating a wafer 200.

(d) The space in which the reflector 530 is disposed in the reflector protective tube 520 is filled with a vacuum atmosphere or an inert-gas atmosphere, so that the reflector 530 can be inhibited from oxidizing. Thus, the reflector 530 can be inhibited from deteriorating over time, with an improvement in thermal reflectivity.

(e) Since the reflector 530 is formed of molybdenum or platinum, a high thermal reflectivity can be achieved. The reflector 530 is higher in thermal reflectivity than the bottom wall of the process container 101 disposed below the heater 23, so that a further improvement can be made in the efficiency of heating a wafer 200.

(f) The reflector 530 is open toward the process chamber 101a and thus is capable of reflecting heat to the process chamber 101a and preventing heat from moving below the process chamber 101a, so that the wafer 200 disposed in the process chamber 101a can be heated efficiently.

(g) The support target 504 having penetrated through the process container 101 is supported by the walls 101e, so that damage can be prevented even when the main heater tube 500 thermally expands due to a flow of current through the heat emitter 540. The power lines 560 and 570 are each disposed inside the support target 504, so that the support target 504 can be supported by the walls 101e.

(h) The gap V is provided between the lid 503 of the main heater tube 500 and the reflector protective tube 520. Thus, even when the main heater tube 500 thermally expands due to a flow of current through the heat emitter 540, the gap V absorbs the thermal expansion of the main heater tube 500, so that the heater 23 can be prevented from being damaged.

(i) The support 240 that supports the heaters 23 is provided on the bottom (protrusion structure 101f) of the process container 101, so that the heaters 23 can be prevented from moving. Thus, the distance between the wafer 200 and each heater 23 can be kept constant.

(j) Since the longitudinal direction of each heater 23 is identical to the direction of movement of the substrate mounting stage 210, each heater 23 is disposed in the longitudinal direction of the process container 101, so that the space in the process container 101 can be effectively used.

### Other Embodiments of the Present Disclosure

The embodiment of the present disclosure has been specifically described above. However, the present disclosure is not limited to the above-described embodiment, and thus various modifications can be made without departing from the gist of the present disclosure.

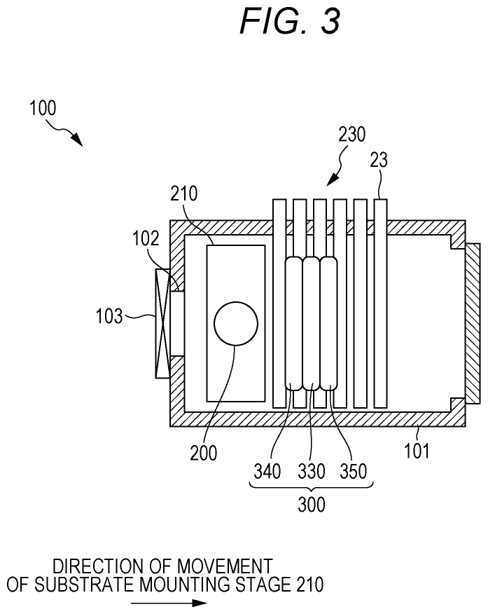

In the above-described embodiment, exemplified has been a case where the longitudinal direction of each heater 23 is identical to the direction of movement of the substrate mounting stage 210. The present disclosure is not limited to the above-described embodiment and thus can be favorably applied to, for example, as illustrated in FIG. 3, a case where the longitudinal direction of each heater 23 intersect the direction of movement of a substrate mounting stage 210. Even in such a case, effects similar to those in the above-described embodiment can be obtained.

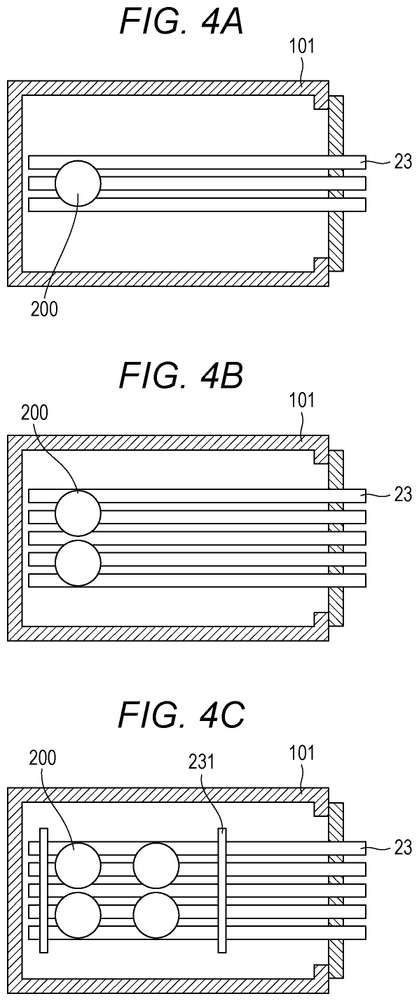

In the above-described embodiment, exemplified has been the heater unit 230 including six heaters 23. The present disclosure is not limited to the above-described embodiment and thus can be favorably applied to, for example, as illustrated in FIG. 4A, a heater unit including three heaters 23. Even in such a case, effects similar to those in the above-described embodiment can be obtained. Note that, referring to FIG. 4A, for example, a substrate mounting stage 210 and a cartridge head assembly 300 are omitted. The same applies to FIGS. 4B and 4C described later.

In the above-described embodiment, exemplified have been the heater unit 230 including six heaters 23 and the substrate processing apparatus 100 of a single-wafer type that processes a single wafer 200 at a time. The present disclosure is not limited to the above-described embodiment and thus can be favorably applied to, for example, as illustrated in FIG. 4B, a heater unit including five heaters 23 and a substrate processing apparatus that processes two wafers 200 at a time. Similarly, for example, as illustrated in FIG. 4C, the present disclosure can be favorably applied to a heater unit including five heaters 23 and a substrate processing apparatus that processes four wafers 200 at a time. As illustrated in FIG. 4C, the present disclosure can be favorably applied to a case where an auxiliary heater 231 that assists the function of heating of the heaters 23 is disposed above the heaters 23. In addition, the present disclosure can be favorably applied to a substrate processing apparatuses of a batch type that processes five to eight wafers 200 at a time. Even in such cases, effects similar to those in the above-described embodiment can be obtained.

In the above-described embodiment, given has been an example in which the heaters 23 are disposed in the process container 101. The present disclosure is not limited to the above-described embodiment and thus can be favorably applied to, for example, a case where heaters (heater unit) are disposed outside a process container 101. Even in such a case, effects similar to those in the above-described embodiment can be obtained.

Even in a case where such substrate processing apparatuses are each used, each piece of processing can be performed in accordance with a processing procedure and processing conditions similar to those in the above-described embodiment and modified examples, leading to obtainment of effects similar to those in the above-described embodiment and modified examples.

The above-described embodiment and modified examples can be used in appropriate combination. For example, such a case can be made similar in processing procedure and processing conditions to the above-described embodiment and modified examples.

### Preferred Embodiments of the Present Disclosure

Supplementary notes of preferred embodiments of the present disclosure will be given below.

(Supplementary Note 1)

According to an embodiment of the present disclosure, provided is a substrate processing apparatus including:
a process chamber in which a substrate is processed;
a heater configured to heat the substrate in the process chamber; and
a housing including the heater and the process chamber, in which
the heater includes:
an outer tube;
an inner tube disposed inside the outer tube; and
a heater wire including a power line disposed in an inner space of the inner tube and a power line that is different from the power line disposed in the inner space of the inner tube and is disposed between the outer tube and the inner tube.

(Supplementary Note 2)

According to another embodiment of the present disclosure, provided is a heater including:
an outer tube;
an inner tube disposed inside the outer tube; and
a heater wire including a power line disposed in an inner space of the inner tube and a power line that is different from the power line disposed in the inner space of the inner tube and is disposed between the outer tube and the inner tube.

(Supplementary Note 3)

According to another embodiment of the present disclosure, provided is a method of manufacturing a semiconductor device, the method including:
supplying power to a heater in a housing, the heater including: an outer tube; an inner tube disposed inside the outer tube; and a heater wire including a power line disposed in an inner space of the inner tube and a power line that is different from the power line disposed in the inner space of the inner tube and is disposed between the outer tube and the inner tube; and
processing a substrate in a process chamber in the housing with the heater kept supplied with the power.

(Supplementary Note 4)

According to another embodiment of the present disclosure, provided is a non-transitory computer-readable recording medium storing a program that causes, by a computer, a substrate processing apparatus to perform a process including:
supplying power to a heater in a housing, the heater including: an outer tube; an inner tube disposed inside the outer tube; and a heater wire including a power line disposed in an inner space of the inner tube and a power line that is different from the power line disposed in the inner space of the inner tube and is disposed between the outer tube and the inner tube; and
processing a substrate in a process chamber in the housing with the heater kept supplied with the power.

According to the present disclosure, there can be provided a technique enabling a high efficiency of heating.

What is claimed is:

1. A substrate processing apparatus comprising:
a process chamber in which a substrate is processed;
a heater configured to heat the substrate in the process chamber; and
a housing including the heater and the process chamber, wherein the heater includes:
an outer tube;
an inner tube disposed inside the outer tube; and
a heater wire including a power line disposed in an inner space of the inner tube and a power line that is different from the power line disposed in the inner space of the inner tube and is disposed between the outer tube and the inner tube.

2. The substrate processing apparatus according to claim 1, further comprising a reflector protective tube provided covering an outer circumference of the outer tube, the reflector protective tube including a reflector.

3. The substrate processing apparatus according to claim 2, further comprising an aligner provided between the reflector protective tube and the outer tube, the aligner aligning a position of the outer tube inside the reflector protective tube.

4. The substrate processing apparatus according to claim 3, wherein the reflector protective tube is provided with the aligner.

5. The substrate processing apparatus according to claim 2, wherein the reflector is open toward the process chamber.

6. The substrate processing apparatus according to claim 2, wherein:
the reflector protective tube has a space in which the reflector is disposed, and
the space is filled with a vacuum atmosphere or an inert-gas atmosphere.

7. The substrate processing apparatus according to claim 2, wherein:
the housing includes a bottom wall disposed below the heater, and
the reflector is higher in thermal reflectivity than the bottom wall of the housing.

8. The substrate processing apparatus according to claim 2, further comprising a mover provided below the heater, the mover being configured to move the substrate, wherein the reflector is provided between the heater wire and the mover.

9. The substrate processing apparatus according to claim 2, wherein the reflector is formed of molybdenum or platinum.

10. The substrate processing apparatus according to claim 1, wherein the outer tube includes:
a support target having penetrated through the housing, the support target being supported by a wall included in the housing; and
a main body continuous with the support target.

11. The substrate processing apparatus according to claim 10, wherein the power line disposed in the inner space of the inner tube and the power line disposed between the outer tube and the inner tube are disposed inside the support target.

12. The substrate processing apparatus according to claim 1, further comprising a thermocouple disposed inside the inner tube.

13. The substrate processing apparatus according to claim 1, wherein the inner tube is formed of an insulator.

14. The substrate processing apparatus according to claim 2, wherein: the outer tube has, at an end, an opening through which the heater wire is in communication and a lid at another end, and
a gap is provided between the lid and the reflector protective tube.

15. The substrate processing apparatus according to claim 1, wherein the heater includes a plurality of heaters each disposed in a longitudinal direction of the housing.

16. The substrate processing apparatus according to claim 1, further comprising a substrate mounting table provided in the process chamber, the substrate mounting table being capable of moving with the substrate mounted on the substrate mounting table, and wherein a longitudinal direction of the heater is identical to a direction of movement of the substrate mounting table.

17. The substrate processing apparatus according to claim 1, further comprising a support provided on a bottom of the housing, the support supporting the heater.

18. The substrate processing apparatus according to claim 2, further comprising a wafer lifter configured to lift up or down the substrate, wherein the reflector is provided between the heater wire and the wafer lifter.

19. The substrate processing apparatus according to claim 1, further comprising a substrate mounting table provided in the process chamber, the substrate mounting table being capable of moving with the substrate mounted on the substrate mounting table, and wherein a longitudinal direction of the heater intersects a direction of movement of the substrate mounting table.

20. A heating apparatus comprising:
an outer tube;
an inner tube disposed inside the outer tube; and
a heater wire including a power line disposed in an inner space of the inner tube and a power line that is different from the power line disposed in the inner space of the inner tube and is disposed between the outer tube and the inner tube.

21. A substrate processing method comprising:
supplying power to a heater in a housing, the heater including: an outer tube; an inner tube disposed inside the outer tube; and a heater wire including a power line disposed in an inner space of the inner tube and a power line that is different from the power line disposed in the inner space of the inner tube and is disposed between the outer tube and the inner tube; and
processing a substrate in a process chamber in the housing with the heater kept supplied with the power.

22. The method of claim 21, further comprising manufacturing a semiconductor device.
